(19) United States
(12) Patent Application Publication
(10) Pub. No.: US 2025/0212500 A1
(43) Pub. Date: Jun. 26, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke ASABA, Himeji Hyogo (JP); Hiroshi KONO, Himeji Hyogo (JP)

(21) Appl. No.: 19/076,947

(22) Filed: Mar. 11, 2025

Related U.S. Application Data
(63) Continuation of application No. PCT/JP2024/005526, filed on Feb. 16, 2024.

(30) Foreign Application Priority Data
Sep. 4, 2023 (JP) 2023-143190

(51) Int. Cl. H10D 84/00; H10D 30/66; H10D 62/832

(52) U.S. Cl. CPC H10D 84/146; H10D 30/66; H10D 62/8325

(57) ABSTRACT

According to one embodiment, a semiconductor device includes a first electrode, a second electrode, a third electrode, a first semiconductor portion, a second semiconductor portion, a third semiconductor portion, and a fourth semiconductor portion. The first semiconductor portion is of a first conductivity type. The first semiconductor portion includes a first semiconductor region, a second semiconductor region, and a third semiconductor region. The second semiconductor portion is of a second conductivity type. The second semiconductor portion includes a first portion, a second portion, a third portion, and a fourth portion. The first portion has a first depth, the second portion has a second depth shallower than the first depth, and the third portion has the first depth. The third semiconductor portion is of the second conductivity type, and includes a first region portion and a second region portion. The fourth semiconductor portion is of the first conductivity type.

### CROSS-REFERENCE TO RELATED APPLICATIONS

This is a continuation application of International Application PCT/JP2024/005526, filed on Feb. 16, 2024. This application also claims priority to Japanese Patent Application No. 2023-143190, filed on Sep. 4, 2023. The entire contents of which are incorporated herein by reference.

### FIELD

Embodiments described herein generally relate to a semiconductor device.

### BACKGROUND

In Semiconductor devices, improving breakdown voltage is desired.

### BRIEF DESCRIPTION OF THE DRAWINGS

FIG. 1 is a schematic cross-sectional view illustrating a semiconductor device according to a first embodiment;

FIG. 2 is a schematic diagram illustrating characteristics of the semiconductor device according to the first embodiment;

FIG. 3 is a schematic cross-sectional view illustrating a semiconductor device according to a comparative example;

FIG. 4 is a schematic diagram illustrating characteristics of a semiconductor device according to a comparative example;

FIG. 5 is a schematic diagram illustrating characteristics of the semiconductor device according to the first embodiment;

FIG. 6 is a schematic cross-sectional view illustrating a semiconductor device according to a second embodiment; and

FIG. 7 is a schematic cross-sectional view illustrating a semiconductor device according to a third embodiment.

### DETAILED DESCRIPTION

According to one embodiment, a semiconductor device includes a first electrode, a second electrode, a third electrode, a first semiconductor portion, a second semiconductor portion, a third semiconductor portion, and a fourth semiconductor portion. The first semiconductor portion is provided between the first electrode and the second electrode, and is of a first conductivity type. The first semiconductor portion includes a first semiconductor region, a second semiconductor region, and a third semiconductor region. The second semiconductor region is provided above the first semiconductor region in a first direction from the first electrode to the second electrode. The first direction crosses a second direction from a cell section to a terminal section. The cell section and the terminal section are set for the first semiconductor portion. An impurity concentration of the first conductivity type in the second semiconductor region is higher than an impurity concentration of the first conductivity type in the first semiconductor region. The third semiconductor region is provided above the first semiconductor region in the first semiconductor region in the terminal section. An impurity concentration of the first conductivity type in the third semiconductor region is higher than the impurity concentration of the first conductivity type in the first semiconductor region. The second semiconductor portion is provided above the first semiconductor portion, and is of a second conductivity type. The second semiconductor portion includes a first portion, a second portion, a third portion, and a fourth portion. The first portion, the second portion, and the third portion are in the cell section and above the second semiconductor region. The first portion has a first depth, the second portion has a second depth shallower than the first depth, and the third portion has the first depth. The second portion is provided between the first portion and the third portion. The first portion, the second portion, and the fourth portion are provided above the third semiconductor region. The third semiconductor portion is of the second conductivity type. The third semiconductor portion includes a first region portion and a second region portion. The first region portion is provided above the first portion, the second portion, and the third portion. The second region portion is provided above the fourth portion. The fourth semiconductor portion is of the first conductivity type. The fourth semiconductor portion is provided above the first portion, the first region portion, and the third portion. The third electrode is provided between the first portion and the second electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

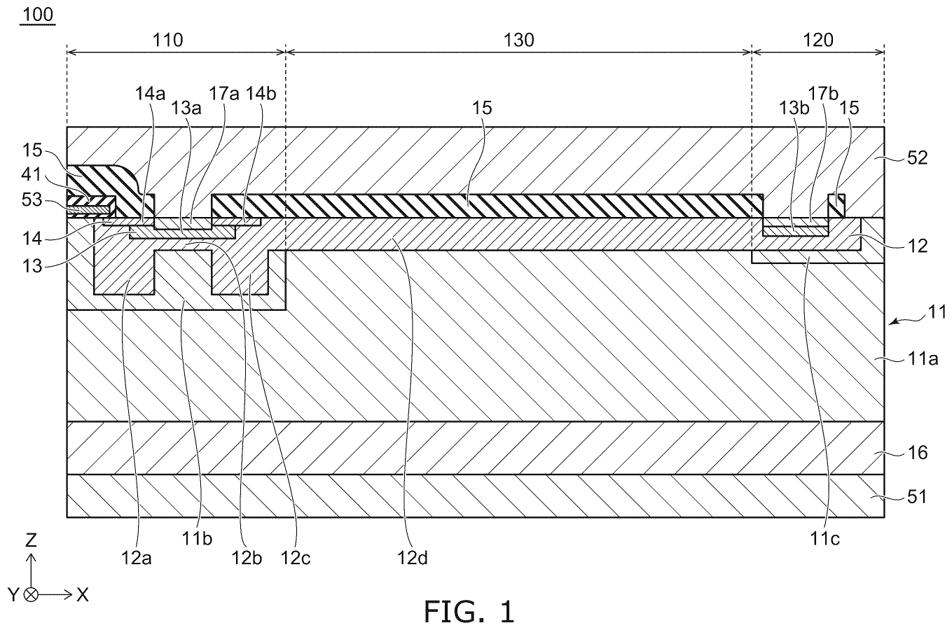

FIG. 1 is a schematic cross-sectional view illustrating a semiconductor device according to a first embodiment.

As shown in FIG. 1, a semiconductor device 100 according to the embodiment includes a first electrode 51, a second electrode 52, a third electrode 53, a first semiconductor portion 11, a second semiconductor portion 12, a third semiconductor portion 13, and a fourth semiconductor portion 14. The first semiconductor portion 11, the second semiconductor portion 12, the third semiconductor portion 13, and the fourth semiconductor portion 14 includes SiC. The first semiconductor portion 11, the second semiconductor portion 12, the third semiconductor portion 13, and the fourth semiconductor portion 14 may include at least one selected from the group consisting of 4H-SiC, 6H-SiC, and 3C-SiC. These semiconductor portions include crystals. These semiconductor portions may include silicon. These semiconductor portions may include a compound semiconductor containing Ga.

A first direction from the first electrode 51 to the second electrode 52 is defined as a Z-axis direction. A second direction perpendicular to the Z-axis direction is defined as an X-axis direction. A third direction perpendicular to the Z-axis direction and the X-axis direction is defined as a Y-axis direction.

As shown in FIG. 1, the semiconductor device 100 includes a cell section 110, a terminal section 120, and a connection section 130. The connection section 130 is provided between the cell section 110 and the terminal section 120. The cell section 110, the terminal section 120, and the connection section 130 are set for the first semiconductor portion 11.

The first semiconductor portion 11 is of a first conductivity type. The second semiconductor portion 12 is of a second conductivity type. The first conductivity type is one of n-type and p-type. The second conductivity type is the other of n-type and p-type. In the following, it is assumed that the first conductivity type is n-type and the second conductivity type is p-type.

The first semiconductor portion 11 is provided between the first electrode 51 and the second electrode 52. The first semiconductor portion 11 includes the cell section 110, the connection section 130, and the terminal section 120. The first semiconductor portion 11 includes a first semiconductor region 11a, a second semiconductor region 11b, and a third semiconductor region 11c.

The second semiconductor region 11b is provided above the first semiconductor region 11a in the X-axis direction (first direction) from the first electrode 51 to the second electrode 52, which crosses the Z-axis direction (second direction) from the cell section 110 to the terminal section 120, and in the cell section 110.

The third semiconductor region 11c is provided above the first semiconductor region 11a in the Z-axis direction and in the terminal section 120.

The impurity concentrations of the first conductivity type in the second semiconductor region 11b and the third semiconductor region 11c are each higher than the impurity concentration in the first semiconductor region 11a. The first semiconductor region 11a is, for example, an n-region. The second semiconductor region 11b and the third semiconductor region 11c are, for example, n⁺-regions. The boundaries among the first semiconductor region 11a, the second semiconductor region 11b, and the third semiconductor region 11c may be clear or unclear.

The second semiconductor portion 12 includes a first portion 12a having a first depth, a second portion 12b having a second depth shallower than the first depth, and a third portion 12c having a first depth provided in the cell section 110. The second portion 12b is provided between the first portion 12a and the third portion 12c. The first portion 12a, the second portion 12b, and a third portion 12c are provided above the second semiconductor region 11b. In the second semiconductor portion 12 includes a fourth portion 12d provided in the terminal section 120. A part of the fourth portion 12d is provided above the third semiconductor region 11c. The depth of the fourth portion 12d is a second depth shallower than the first depth. Here, the depth corresponds to, for example, the position in the Z-axis direction (first direction) based on the position of the first electrode 51 in the first direction. The distance along the first direction between the first electrode 51 and the first portion 12a is shorter than the distance along the first direction between the first electrode 51 and the second portion 12b. The distance along the first direction between the first electrode 51 and the third portion 12c is shorter than the distance along the first direction between the first electrode 51 and the second portion 12b. The distance along the first direction between the first electrode 51 and the fourth portion 12d is longer than the distance along the first direction between the first electrode 51 and the first portion 12a. The distance along the first direction between the first electrode 51 and the fourth portion 12d is longer than the distance along the first direction between the first electrode 51 and the third portion 12c. In one example, the length of the fourth portion 12d along the second direction may be longer than the length of the third portion 12c along the second direction.

The boundaries among the first portion 12a, the second portion 12b, the third portion 12c, and the fourth portion 12d may be clear or unclear. The first portion 12a, the second portion 12b, the third portion 12c, and the fourth portion 12d are semiconductor regions each indicating a part of the second semiconductor portion 12.

In the terminal section 120, a third semiconductor region 11c is provided above the side and bottom surfaces of the fourth portion 12d. In the terminal section 120, a part of the third semiconductor region 11c is electrically connected to the second electrode 52. For example, the distance along the first direction between the first electrode 51 and the third semiconductor region 11c is longer than the distance along the first direction between the first electrode 51 and the third portion 12c. For example, the distance along the first direction between the first electrode 51 and the third semiconductor region 11c is shorter than the distance along the first direction between the first electrode 51 and the fourth portion 12d. For example, the distance along the first direction between the first electrode 51 and the third semiconductor region 11c is longer than the distance along the first direction between the first electrode 51 and the second semiconductor region 11b.

The third semiconductor portion 13 is of the second conductivity type. The impurity concentration of the second conductivity type in the third semiconductor portion 13 is higher than the impurity concentration of the second conductivity type in the second semiconductor portion 12. The third semiconductor portion 13 is, for example, a p⁺⁺-region. The third semiconductor portion 13 includes a first region portion 13a and a second region portion 13b. The first region portion 13a is provided above the first portion 12a, the second portion 12b, and the third portion 12c. A part of the first region portion 13a is electrically connected to the second electrode 52. For example, the first region portion 13a makes ohmic contact with the second electrode 52. The second region portion 13b is provided above the fourth portion 12d in the terminal section 120. In the first region portion 13a and the second region portion 13b, the boundary may be clear or unclear. The first region portion 13a and the second region portion 13b are semiconductor regions each indicating a part of the third semiconductor portion 13.

The fourth semiconductor portion 14 is of the first conductivity type. The impurity concentration of the first conductivity type in the fourth semiconductor portion 14 is higher than the impurity concentration of the first conductivity type in the first semiconductor portion 11. The fourth semiconductor portion 14 is, for example, an n⁺⁺-region. The fourth semiconductor portion 14 is provided above the first portion 12a, the first region portion 13a, and the second portion 12b. The fourth semiconductor portion 14 includes a first region 14a and a second region 14b. The first region 14a is provided above the first portion 12a. The second region 14b is provided above the second portion 12b. A part of the fourth semiconductor portion 14 is electrically connected to the second electrode 52. For example, the fourth semiconductor portion 14 makes ohmic contact with the second electrode 52. In the first region 14a and the second region 14b, the boundary may be clear or unclear. The first region 14a and the second region 14b are semiconductor regions each indicating a part of the fourth semiconductor portion 14.

A first insulating portion 41 is provided around the third electrode 53. A part of the first insulating portion 41 is provided between the second semiconductor region 11b and the third electrode 53. The first insulating portion 41 includes, for example, SiO₂. Further, the semiconductor device 100 may be provided with an insulating portion 15. The insulating portion 15 is provided between the fourth semiconductor portion 14 and the second electrode 52, between the fourth portion 12d and the second electrode 52, and between the fourth portion 12d and the second electrode 52.

As shown in FIG. 1, the fifth semiconductor portion 16 is provided between the first electrode 51 and the first semiconductor portion 11 in the first direction. The first conductivity type impurity concentration in the fifth semiconductor portion 16 is higher than the first impurity concentration in the first semiconductor portion 11. The fifth semiconductor portion 16 may correspond to, for example, at least one of a buffer layer and a substrate. A low resistance electrical connection is obtained.

For example, as shown in FIG. 1, the semiconductor device 100 may be provided with a first silicide 17a and a second silicide 17b. The first silicide 17a is provided in the cell section 110. The first silicide 17a is provided between the first region portion 13a and the second electrode 52 in the first direction. At least a part of the first silicide 17a is provided between the first region 14a and the second region 14b in the second direction. The second silicide 17b is provided at the terminal section 120. The second silicide 17b is provided between the second region portion 13b and the second electrode 52 in the first direction.

In the semiconductor device 100, the current flowing between the first electrode 51 and the second electrode 52 can be controlled by the potential of the third electrode 53. The potential of the third electrode 53 may be, for example, a potential based on the potential of the second electrode 52. The first electrode 51 functions, for example, as a drain electrode. The second electrode 52 functions, for example, as a source electrode. The third electrode 53 functions as, for example, a gate electrode. The semiconductor device 100 is, for example, a transistor. The semiconductor device 100 is, for example, a MOSFET (Metal-Oxide-Semiconductor Field Effect Transistor) having a built-in Schottky barrier diode.

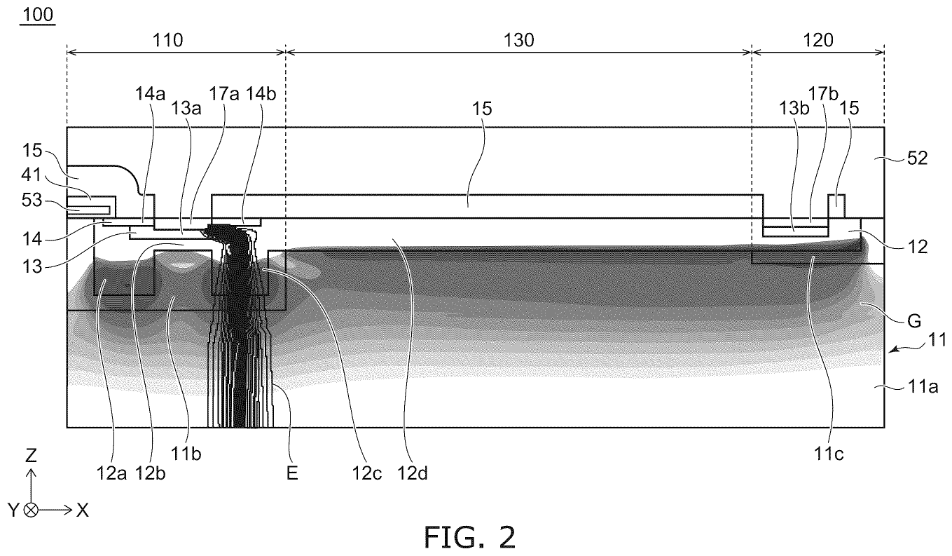

FIG. is a the 2 schematic diagram illustrating characteristics of the semiconductor device 100. In FIG. 2, the first electrode 51 and the fifth semiconductor portion 16 are omitted. In FIG. 2, the electric field is high in dark regions and low in pale regions. In the cell section 110, the current E flows in the Y-axis direction through the second portion 12b.

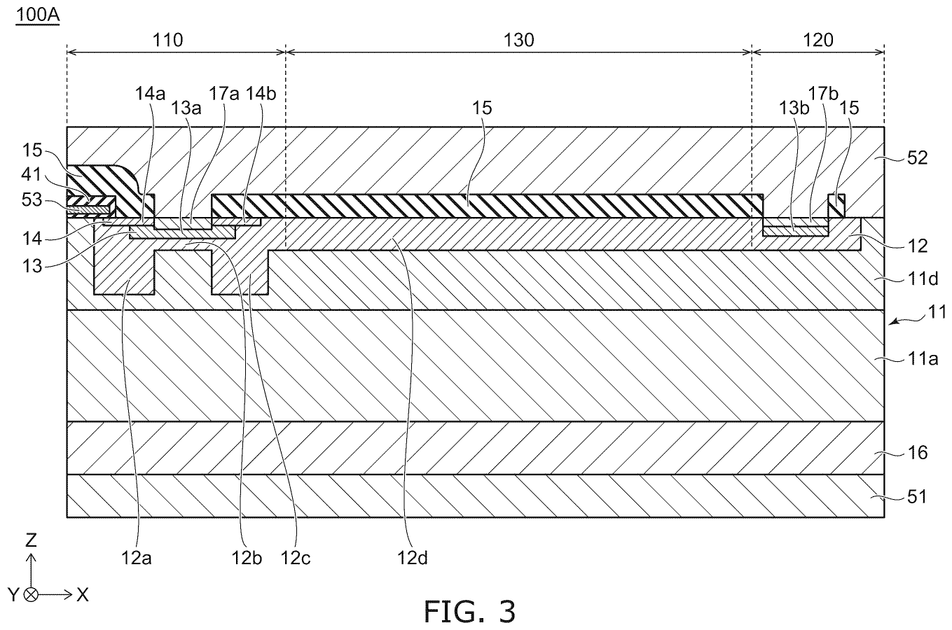

FIG. 3 is a schematic cross-sectional view illustrating a semiconductor device 100A of a comparative example. In FIG. 3, the same components as the semiconductor device 100 are given the same reference numerals. In the semiconductor device 100A, a fourth semiconductor region 11d, in which the second semiconductor region 11b of the cell section 110 and the third semiconductor region 11c of the terminal section 120 are connected, is provided above the first semiconductor region 11a. The fourth semiconductor region 11d is n-type. The impurity concentration of the first conductivity type in the fourth semiconductor region 11d is higher than the impurity concentration in the first semiconductor region 11a.

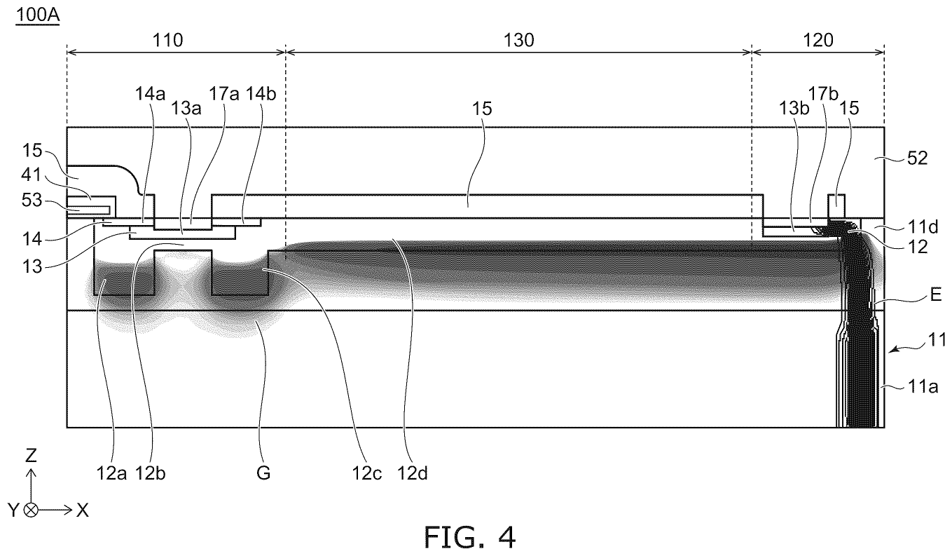

FIG. 4 is a schematic diagram illustrating the characteristics of a semiconductor device 100A of a comparative example. In FIG. 4, the electric field is high in dark regions and low in pale regions. In the terminal section 120, the current E flows in the Y-axis direction through the end portion of the fourth portion 12d.

As shown in FIG. 4, when the fourth semiconductor region 11d is provided from the cell section 110 to the terminal section 120 via the connection section 130, the electric field becomes stronger at the terminal section 120, and the breakdown voltage of the semiconductor device 100A becomes lower. On the other hand, as shown in FIG. 2, in the semiconductor device 100 of the embodiment, the second semiconductor region 11b in the cell section 110 and the third semiconductor region 11c in the terminal section 120 are provided to be separated in the X-axis direction. Thereby, the electric field at the first portion 12a and the second portion 12b can be strengthened. Therefore, in a region from the cell section 110 to the terminal section 120, the electric field distribution shown in FIG. 2 is more relaxed than the electric field distribution shown in FIG. 4. The breakdown voltage of the semiconductor device 100 can be improved.

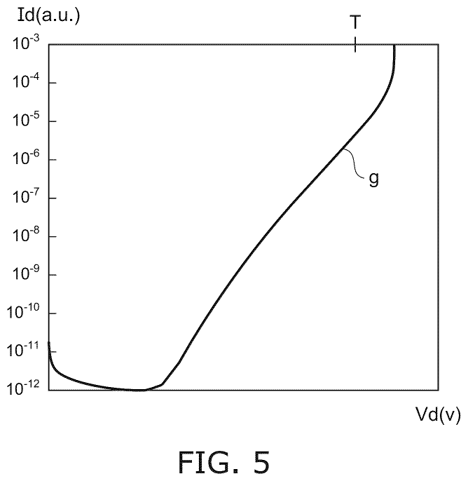

FIG. 5 is a diagram showing an example of the breakdown voltage of the semiconductor device 100.

The horizontal axis in FIG. 5 is the drain voltage. The vertical axis is the drain current. In the semiconductor device 100, the breakdown voltage exceeds the target voltage value T. The voltage value T is, for example, 1600V.

In the semiconductor device 100, the second semiconductor region 11b and the third semiconductor region 11c are provided. The second semiconductor region 11b and the third semiconductor region 11c each become a current spreading layer.

In the cell section 110, the first portion 12a and the third portion 12c having the first depth are provided above the second semiconductor region 11b. For example, the electric field in the first portion 12a and the third portion 12c can be reduced by the second semiconductor region 11b. Thereby, the electric field from the cell section 110 to the terminal section 120 can be relaxed, and the breakdown voltage of the semiconductor device 100 can be improved.

In the terminal section 120, the third semiconductor region 11c makes Schottky contact with the second electrode 52. A Schottky barrier diode (SBD) is formed in a region including the third semiconductor region 11c, the second electrode 52, and the contact region. Thereby, the operation of the parasitic diode in the terminal section 120 can be controlled. By increasing the contact region, it is possible to increase the unipolar current.

### Second Embodiment

The second embodiment differs in that a fifth portion 12e is provided. Therefore, the difference due to the providing the fifth portion 12e will be explained. The same components as in the first embodiment are given the same reference numerals, and detailed explanations will be omitted.

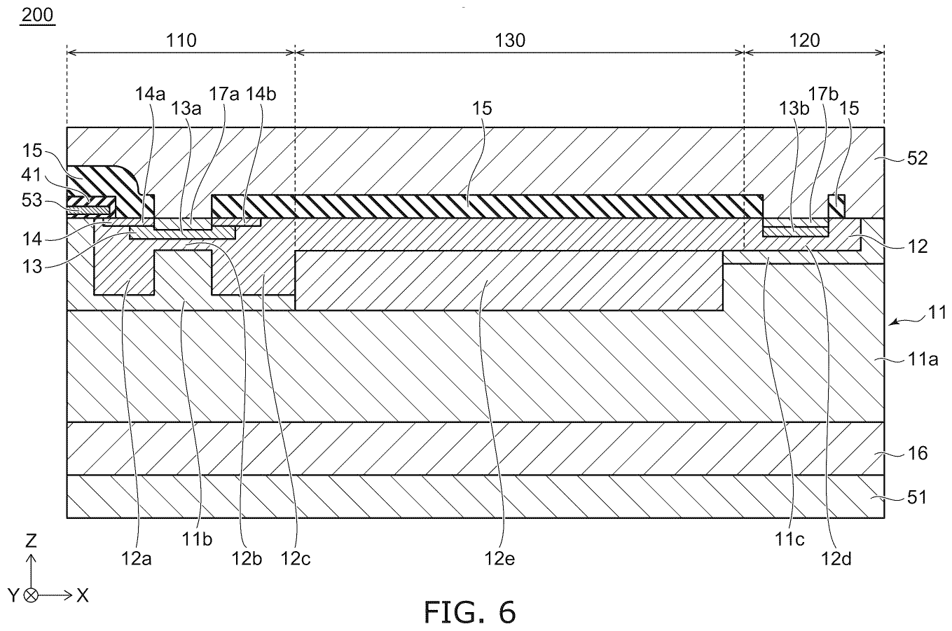

FIG. 6 is a schematic cross-sectional view illustrating a semiconductor device according to the second embodiment.

As shown in FIG. 6, in a semiconductor device 200 according to the embodiment, the second semiconductor portion 12 includes a fifth portion 12e in a connection section 130. The configuration of the semiconductor device 200 except for this may be the same as that of the semiconductor device 100.

The depth of the fifth portion 12e is a third depth in the first direction. The third depth is deeper than the first depths of the first portion 12a and the third portion 12c. In this example, the position (depth) of the lower end of the fifth portion 12e is substantially the same as the position (depth) of the lower ends of the second semiconductor region 11b. The distance along the first direction between the first electrode 51 and the fifth portion 12e is longer than the distance along the first direction between the first electrode 51 and the third portion 12c.

In the semiconductor device 200, by providing the fifth portion 12e, the electric field at the end of the third portion 12c can be further relaxed. In the semiconductor device 200, the breakdown voltage cab be further improved.

### Third Embodiment

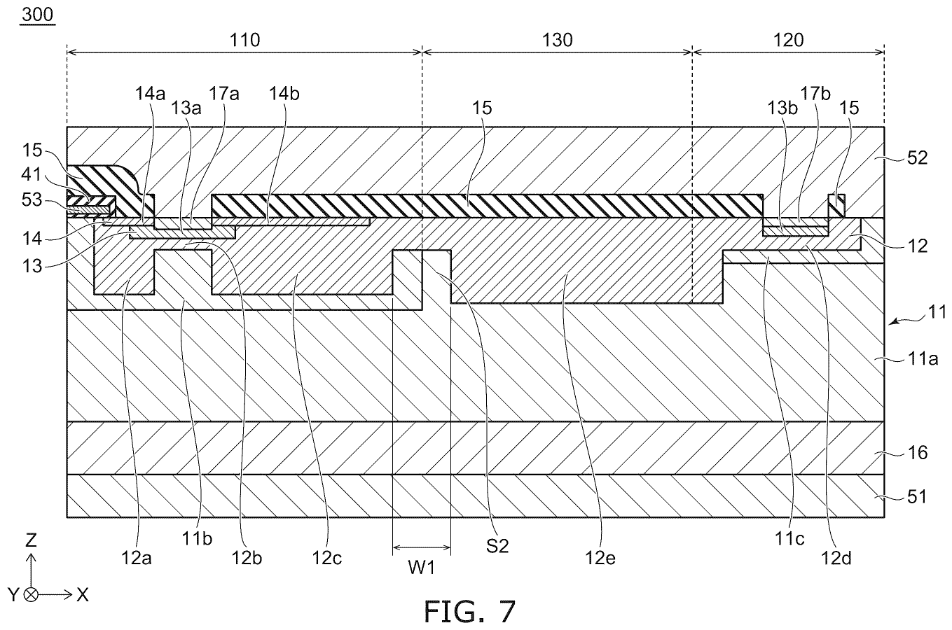

FIG. 7 is a schematic cross-sectional view illustrating a semiconductor device according to a third embodiment.

As shown in FIG. 7, in a semiconductor device 300 according to the embodiment, the configurations of the cell section 110 and the connection section 130 are different from those in the semiconductor device 100. The configuration of the semiconductor device 300 except for this may be the same as the configuration of the semiconductor device 100 or the semiconductor device 200.

In the semiconductor device 300, the third portion 12c of the cell section 110 extends toward the connection section 130. The second region 14b above the second portion 12b also extends toward the connection section 130.

A gap S2 is provided in the second semiconductor portion 12. The gap S2 is provided at the connection portion between the cell section 110 and the connection section 130. The width W1 of the gap S2 is, for example, not less than 0.1 μm and not more than 10 μm. The width W1 may be, for example, 1 μm.

The depth of the lower end of the second semiconductor portion 12 positioned above the gap S2 may be substantially the same as the depth of the lower end of the third semiconductor portion 13, for example.

In the semiconductor device 300, the fifth portion 12e includes the gap S2. By providing the gap S2, the electric field can be further relaxed compared to the semiconductor device 200 of the second embodiment. In the semiconductor device 300, the breakdown voltage can be further improved.

In the embodiment, for example, the first conductivity type impurity includes at least one selected from the group consisting of N, P, and As. For example, the second conductivity type impurity includes at least one selected from the group consisting of B, Al, and Ga.

In one example, the concentration of the first conductivity type impurity in the first semiconductor portion 11 is, for example, not less than 1×10¹⁴ cm⁻³ and not more than 1×10¹⁷ cm⁻³. In one example, the concentration of the second conductivity type impurity in the second semiconductor portion 12 is, for example, not less than 1×10¹⁶ cm⁻³ and not more than 1×10²⁰ cm⁻³. In one example, the concentration of the second conductivity type impurity in the third semiconductor portion 13 is, for example, not less than 1×10¹⁹ cm⁻³ and not more than 1×10²¹ cm⁻³. In one example, the concentration of the first conductivity type impurity in the fourth semiconductor portion 14 is, for example, not less than 1×10¹⁹ cm⁻³ and not more than 1×10²¹ cm⁻³. In one example, the concentration of the first conductivity type impurity in the fifth semiconductor portion 16 is, for example, not less than 1×10¹⁵ cm⁻³ and not more than 1×10¹⁸ cm⁻³. The above impurity concentrations may be substantially carrier concentrations, for example.

In embodiments, information regarding length and thickness is obtained by electron microscopy or the like. Information regarding the composition of the material can be obtained by SIMS (Secondary Ion Mass Spectrometry) or EDX (Energy dispersive X-ray spectroscopy).

The embodiment includes the following aspects.

### (Additional Note 1)

A semiconductor device, comprising:
a first electrode;
a second electrode;
a first semiconductor portion of a first conductivity type, the first semiconductor portion being provided between the first electrode and the second electrode, the first semiconductor portion including
   a first semiconductor region,
   a second semiconductor region provided above the first semiconductor region in a first direction from the first electrode to the second electrode, the first direction crossing a second direction from a cell section to a terminal section, the cell section and the terminal section being set for the first semiconductor portion, an impurity concentration of the first conductivity type in the second semiconductor region being higher than an impurity concentration of the first conductivity type in the first semiconductor region, and
   a third semiconductor region provided above the first semiconductor region in the first semiconductor region in the terminal section, an impurity concentration of the first conductivity type in the third semiconductor region being higher than the impurity concentration of the first conductivity type in the first semiconductor region;
a second semiconductor portion of a second conductivity type provided above the first semiconductor portion, the second semiconductor portion including a first portion, a second portion, a third portion, and a fourth portion, the first portion, the second portion, and the third portion being in the cell section and above the second semiconductor region, the first portion having a first depth, the second portion having a second depth shallower than the first depth, the third portion having the first depth, the second portion being provided between the first portion and the third portion, the first portion, the second portion, the fourth portion being provided above the third semiconductor region;
a third semiconductor portion of the second conductivity type, the third semiconductor portion including a first region portion and a second region portion, the first region portion being provided above the first portion, the second portion, and the third portion, the second region portion being provided above the fourth portion;
a fourth semiconductor portion of the first conductivity type, the fourth semiconductor portion being provided above the first portion, the first region portion, and the third portion; and
a third electrode provided between the first portion and the second electrode.

### (Additional Note 2)

The semiconductor device according to Additional Note 1, wherein
the third semiconductor region and the second electrode are in Schottky contact.
   (Additional Note 3). The semiconductor device according to Additional Note 1 or 2, wherein
a connection section is further set for the first semiconductor portion,
the connection section is provided between the cell section and the terminal section in the second direction,
the second semiconductor portion further includes a fifth portion,
the fifth portion is provided above the first semiconductor region in the connection section, and
at least a part of the fifth portion has a third depth deeper than the first depth.

### (Additional Note 4)

The semiconductor device according to Additional Note 3, wherein
the fifth portion includes a gap.

### (Additional Note 5)

The semiconductor device according to any one of Additional Notes 1-4, further comprising:
a first insulating portion,
at least a part of the first insulating portion being provided between the first portion and the third electrode.

### (Additional Note 6)

The semiconductor device according to any one of Additional Notes 1-5, wherein
an impurity concentration of the first conductivity type in the fourth semiconductor portion is higher than an impurity concentration of the first conductivity type in the first semiconductor portion,
an impurity concentration of the second conductivity type in the third semiconductor portion is higher than an impurity concentration of the second conductivity type in the second semiconductor portion.

### (Additional Note 7)

The semiconductor device according to any one of Additional Notes 1-6, wherein
a part of the third semiconductor portion and a part of the fourth semiconductor portion are in ohmic contact with the second electrode.

### (Additional Note 8)

The semiconductor device according to any one of Additional Notes 1-7, further comprising:
a first silicide provided in the cell section,
the first silicide being provided between the first region portion and the second electrode in the first direction, and
at least a part of the first silicide being provided between the first region and the second region in the second direction.

### (Additional Note 9)

The semiconductor device according to any one of Additional Notes 1-8, further comprising:
a fifth semiconductor portion of the first conductivity type,
the fifth semiconductor portion being provided between the first electrode and the first semiconductor portion in the first direction, and
an impurity concentration of the first conductivity type in the fifth semiconductor portion being higher than an impurity concentration of the first conductivity type in the first semiconductor portion.

### (Additional Note 10)

The semiconductor device according to any one of Additional Notes 1-9, wherein
the first depth and the second depth correspond to a position in the first direction based on a position of the first electrode in the first direction.

### (Additional Note 11)

The semiconductor device according to any one of Additional Notes 1-10, wherein
the first semiconductor portion, the second semiconductor portion, the third semiconductor portion, and the fourth semiconductor portion include SiC.

According to the embodiment, a semiconductor device capable of improving breakdown voltage is provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor portions, insulating portions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a first semiconductor portion of a first conductivity type, the first semiconductor portion being provided between the first electrode and the second electrode, the first semiconductor portion including
a first semiconductor region,
a second semiconductor region provided above the first semiconductor region in a first direction from the first electrode to the second electrode, the first direction crossing a second direction from a cell section to a terminal section, the cell section and the terminal section being set for the first semiconductor portion, an impurity concentration of the first conductivity type in the second semiconductor region being higher than an impurity concentration of the first conductivity type in the first semiconductor region, and
a third semiconductor region provided above the first semiconductor region in the first semiconductor region in the terminal section, an impurity concentration of the first conductivity type in the third semiconductor region being higher than the impurity concentration of the first conductivity type in the first semiconductor region;
a second semiconductor portion of a second conductivity type provided above the first semiconductor portion, the second semiconductor portion including a first portion, a second portion, a third portion, and a fourth portion, the first portion, the second portion, and the third portion being in the cell section and above the second semiconductor region, the first portion having a first depth, the second portion having a second depth shallower than the first depth, the third portion having the first depth, the second portion being provided between the first portion and the third portion, the first portion, the second portion, the fourth portion being provided above the third semiconductor region;
a third semiconductor portion of the second conductivity type, the third semiconductor portion including a first region portion and a second region portion, the first region portion being provided above the first portion, the second portion, and the third portion, the second region portion being provided above the fourth portion;
a fourth semiconductor portion of the first conductivity type, the fourth semiconductor portion being provided above the first portion, the first region portion, and the third portion; and
a third electrode provided between the first portion and the second electrode.

2. The device according to claim 1, wherein
the third semiconductor region and the second electrode are in Schottky contact.

3. The device according to claim 1, wherein
a connection section is further set for the first semiconductor portion, the connection section is provided between the cell section and the terminal section in the second direction,
the second semiconductor portion further includes a fifth portion,
the fifth portion is provided above the first semiconductor region in the connection section, and
at least a part of the fifth portion has a third depth deeper than the first depth.

4. The device according to claim 3, wherein
the fifth portion includes a gap.

5. The device according to claim 1, further comprising:
a first insulating portion,
at least a part of the first insulating portion being provided between the first portion and the third electrode.

6. The device according to claim 1, wherein
an impurity concentration of the first conductivity type in the fourth semiconductor portion is higher than an impurity concentration of the first conductivity type in the first semiconductor portion,
an impurity concentration of the second conductivity type in the third semiconductor portion is higher than an impurity concentration of the second conductivity type in the second semiconductor portion.

7. The device according to claim 1, wherein
a part of the third semiconductor portion and a part of the fourth semiconductor portion are in ohmic contact with the second electrode.

8. The device according to claim 1, wherein
the first depth and the second depth correspond to a position in the first direction based on a position of the first electrode in the first direction.

9. The device according to claim 1, wherein
the first semiconductor portion, the second semiconductor portion, the third semiconductor portion, and the fourth semiconductor portion include SiC.

10. The device according to claim 1, further comprising:
a first silicide provided in the cell section,
the first silicide being provided between the first region portion and the second electrode in the first direction, and
at least a part of the first silicide being provided between the first region and the second region in the second direction.

11. The device according to claim 1, further comprising:
a fifth semiconductor portion of the first conductivity type,
the fifth semiconductor portion being provided between the first electrode and the first semiconductor portion in the first direction, and
an impurity concentration of the first conductivity type in the fifth semiconductor portion being higher than an impurity concentration of the first conductivity type in the first semiconductor portion.

12. The device according to claim 1, wherein
a distance along the first direction between the first electrode and the first portion is shorter than a distance along the first direction between the first electrode and the second portion, and
a distance between the first electrode and the third portion along the first direction is shorter than the distance between the first electrode and the second portion along the first direction.

13. The device according to claim 12, wherein
a distance between the first electrode and the fourth portion along the first direction is longer than the distance between the first electrode and the first portion along the first direction, and longer than the distance along the first direction between the first electrode and the third portion.

14. The device according to claim 3, wherein
a distance between the first electrode and the fifth portion along the first direction is longer than a distance between the first electrode and the third portion along the first direction.

15. The device according to claim 1, wherein
a distance between the first electrode and the third semiconductor region along the first direction is longer than a distance between the first electrode and the third portion along the first direction.

16. The device according to claim 1, wherein
a distance between the first electrode and the third semiconductor region along the first direction is shorter than a distance between the first electrode and the fourth portion along the first direction.

17. The device according to claim 1, wherein
a distance between the first electrode and the third semiconductor region along the first direction is longer than a distance between the first electrode and the second semiconductor region along the first direction.

18. The device according to claim 1, further comprising:
a second silicide provided in the terminal section,
the second silicide being provided between the second region portion and the second electrode in the first direction.

19. The device according to claim 4, wherein
a width of the gap is not less than 0.1 μm and not more than 10 μm.

20. The device according to claim 1, wherein
a length of the fourth portion along the second direction is longer than a length of the third portion along the second direction.
